(19) United States
(12) Patent Application Publication
(10) Pub. No.: US 2026/0114157 A1
(43) Pub. Date: Apr. 23, 2026

(54) DISPLAY DEVICE

(71) Applicant: Samsung Display Co., Ltd., Yongin-si (KR)

(72) Inventors: HYOUNGJOO LEE, Yongin-si (KR); SEONHYE KIM, Yongin-si (KR); MINSU KIM, Yongin-si (KR); KYOUNGWOO PARK, Yongin-si (KR)

(21) Appl. No.: 19/281,084

(22) Filed: Jul. 25, 2025

(30) Foreign Application Priority Data
Oct. 18, 2024 (KR) 10-2024-0142899

(51) Int. Cl. H10K 59/80

(52) U.S. Cl. CPC H10K 59/873

(57) ABSTRACT

A display device includes a display panel including a first to third regions, and a lower module disposed between the first region and the third region in a state where the second region is bent, where the lower module includes a first protective member, a second protective member, and a cover member disposed between the first protective member and the second protective member. The cover member includes an intermediate layer, a first adhesive disposed on the intermediate layer and in contact with the first protective member, a second adhesive disposed under the intermediate layer, a heat dissipation layer between the second protective member and the second adhesive.

This application claims priority to Korean Patent Application No. 10-2024-0142899, filed on Oct. 18, 2024, and all the benefits accruing therefrom under 35 U.S.C. § 119, the content of which in its entirety is herein incorporated by reference.

### BACKGROUND

### (1) Field

The present disclosure relates to a display device, and more particularly, to a display device with improved surface quality.

### (2) Description of the Related Art

Various display devices are being developed for use in multimedia devices such as a television, a mobile phone, a tablet computer, a navigation system, and a game console. Nowadays, to reduce a dead space of the display device, a display panel of which one region is bent and accommodated in a housing is being developed.

### SUMMARY

In a display panel of which one region is bent and accommodated in a housing, the process of compressing parts during bending may cause the surface quality of a display panel to be reduced.

The present disclosure provides a display device with improved surface quality of a display panel in a process of compressing during bending.

An embodiment of the invention provides a display device including a display panel including a first region including an active region in which pixels are arranged, a second region bent with respect to a bending axis extending along a first direction, and a third region spaced apart from the first region along a second direction crossing the first direction with the second region therebetween, and a lower module disposed between the first region and the third region in a state where the second region is bent, where the lower module includes a first protective member disposed on the first region, a second protective member disposed on the third region, and a cover member disposed between the first protective member and the second protective member. In such an embodiment, the cover member includes an intermediate layer, a first adhesive disposed on the intermediate layer and in contact with the first protective member, a second adhesive disposed under the intermediate layer, a heat dissipation layer between the second protective member and the second adhesive.

In an embodiment, each of the first adhesive and the second adhesive may include a pressure sensitive adhesive (PSA).

In an embodiment, the intermediate layer may include polyethylene terephthalate (PET).

In an embodiment, the intermediate layer may have a black color.

In an embodiment, a thickness of the cover member may be in a range of about 100 micrometers (μm) to about 250 μm.

In an embodiment, a thickness of the first adhesive and a thickness of the second adhesive may be each in a range of about 5 μm to about 200 μm.

In an embodiment, a thickness of the intermediate layer may be in a range of about 4 μm to about 100 μm, and a thickness of the heat dissipation layer may in a range of be about 5 μm to about 100 μm.

In an embodiment, a modulus of the first adhesive and a modulus of the second adhesive may be different from each other.

In an embodiment, a modulus of the first adhesive and a modulus of the second adhesive may be each in a range of about 0.003 megapascals (Mpa) to about 0.5 Mpa.

In an embodiment, a thickness of the first adhesive may be smaller than a thickness of the second adhesive.

In an embodiment, a modulus of the first adhesive may be smaller than a modulus of the second adhesive.

In an embodiment, the cover member may further include an additional intermediate layer disposed under the second adhesive and an additional adhesive disposed between the additional intermediate layer and the heat dissipation layer.

In an embodiment, the display device may further include an adhesive layer which bonds the second protective member and the heat dissipation layer to each other.

In an embodiment, the display device may further include a window disposed on the display panel and an optical film disposed between the display panel and the window.

In an embodiment, the display device may further include a transparent adhesive layer disposed between the window and the optical film, and the transparent adhesive layer may include an optically clear adhesive (OCA) film.

In an embodiment, the display device may further include a bending cover layer disposed on the second region and a protective layer disposed in a space between the second region and a side surface of the first protective member facing the second region, a side surface of the cover member, and a side surface of the second protective member, wherein the protective layer includes a resin.

An embodiment of the invention provides an electronic device including window, a display panel including a first region disposed in which pixels are arranged, a second region bent with respect to a bending axis extending along a first direction, and a third region spaced apart from the first region along a second direction crossing the first direction with the second region therebetween, and a lower module disposed between the first region and the third region in a state where the second region is bent, wherein the lower module includes a first protective member disposed on the first region, a second protective member disposed on the third region, and a cover member disposed between the first protective member and the second protective member, and a case coupled with the window, wherein the cover member includes; an intermediate layer, a first adhesive disposed on the intermediate layer and in contact with the first protective member, a second adhesive disposed under the intermediate layer, and a heat dissipation layer between the second protective member and the second adhesive.

In an embodiment, each of the first adhesive and the second adhesive comprises a pressure sensitive adhesive.

In an embodiment, the intermediate layer comprises polyethylene terephthalate.

In an embodiment, the intermediate layer has a black color.

### BRIEF DESCRIPTION OF THE DRAWINGS

The above and other features of embodiments of the invention will become more apparent by describing in further detail embodiments thereof with reference to the accompanying drawings, in which:

FIG. 1 is a perspective view of an electronic device according to an embodiment of the invention;

FIG. 2 is an exploded perspective view of a display device according to an embodiment of the invention;

FIG. 3 is a cross-sectional view taken along line I-I′ of FIG. 2;

FIG. 4 is a cross-sectional view illustrating a display panel in a bent state according to an embodiment of the invention;

FIG. 5 is a plan view of a display panel according to an embodiment of the invention;

FIG. 6 is a plan view of an input sensor according to an embodiment of the invention;

FIG. 7 is a cross-sectional view of a cover member according to an embodiment of the invention;

FIG. 8 is a cross-sectional view of a cover member according to an embodiment of the invention;

FIG. 9 is a cross-sectional view of a cover member according to an embodiment of the invention;

FIG. 10 is a cross-sectional view of a cover member according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

In this specification, it will be understood that when an element (or a region, a layer, a portion, or the like) is referred to as being “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an. ” “Or” means “and/or. ” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention are described with reference to the drawings.

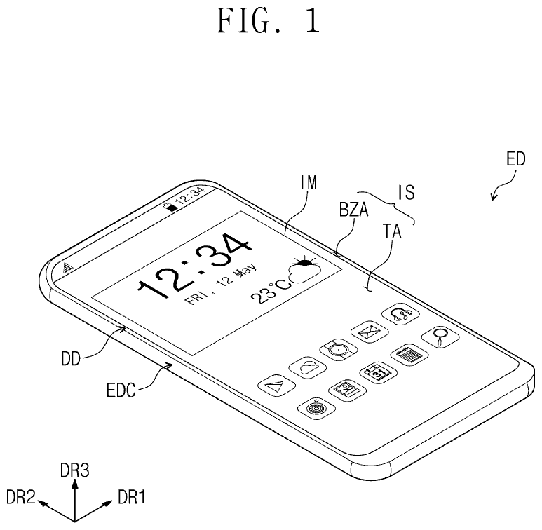

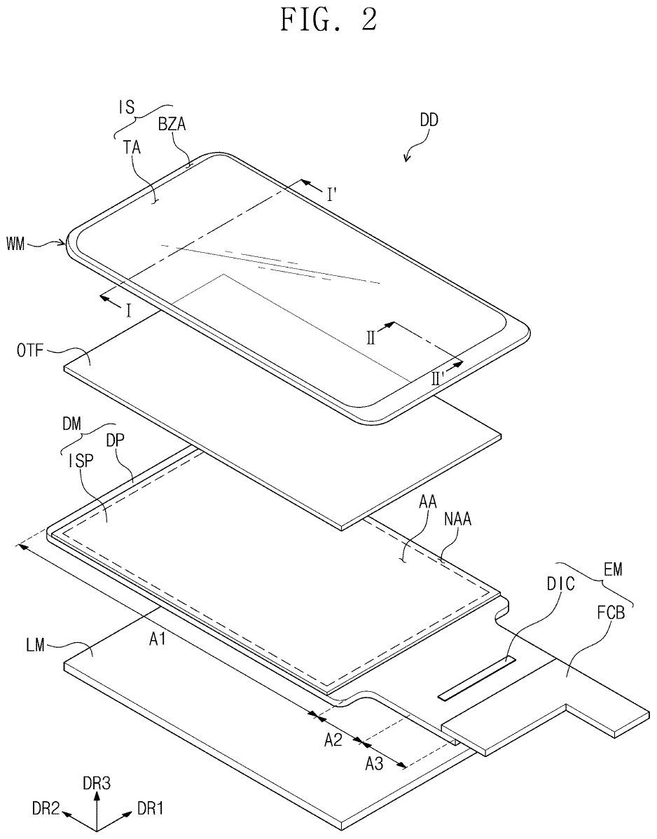

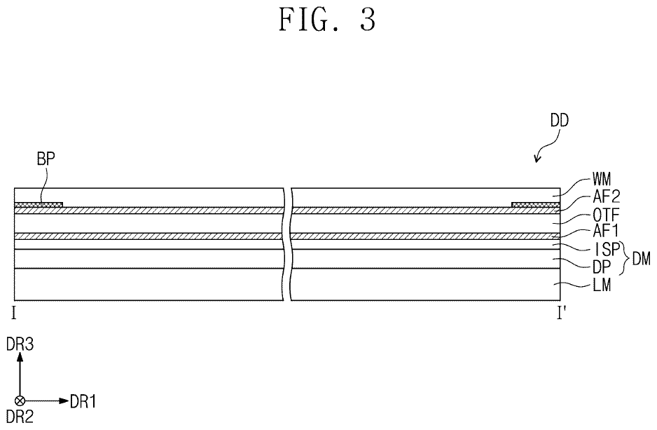

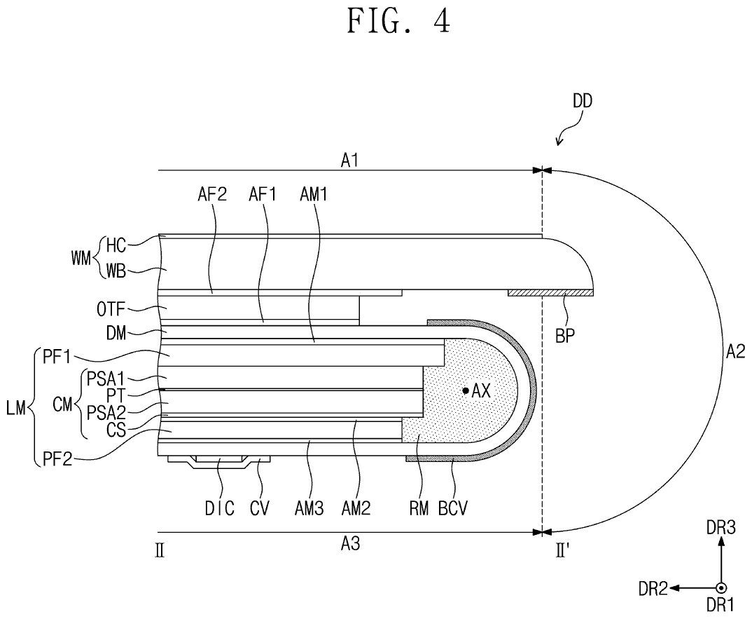

FIG. 1 is a perspective view of an electronic device according to an embodiment of the invention. FIG. 2 is an exploded perspective view of a display device according to an embodiment of the invention. FIG. 3 is a cross-sectional view taken along line I-I′ of FIG. 2. FIG. 4 is a cross-sectional view taken along line II-II′ of FIG. 2 in a state where a region of a display panel is bent.

Referring to FIGS. 1 to 3, an embodiment of the electronic device ED may be activated in response to an electrical signal. The electronic device ED may include various types of electronic device. For example, the electronic device ED may be a display device including a screen such as a smartwatch, a tablet computer, a laptop, a computer, or a smart television.

The electronic device ED may display an image IM in a third direction DR3 on a display surface IS parallel to each of a first direction DR1 and a second direction DR2. The display surface IS on which the image IM is displayed may correspond to a front surface of the electronic device ED. The image IM may include a still image as well as a moving image.

In an embodiment, a front surface (or an upper surface) and a back surface (or a lower surface) of each member may be defined based on the third direction in which the image IM is displayed. The front surface and the back surface are opposed to each other in the third direction DR3, and a normal direction of each of the front surface and the back surface may be parallel to the third direction DR3.

A separation distance between the front surface and the back surface in the third direction DR3 may correspond to a thickness of the electronic device ED in the third direction DR3. In the disclosure, directions indicated by the first to third directions DR1, DR2, and DR3 are relative concepts and may be changed into other directions.

The electronic device ED may detect an external input applied from the outside. The external input may include various types of inputs provided from the outside of the electronic device ED. For example, the external input may include a touch by a portion of a body of a user, such as a user's hand, as well as an external input (for example, hovering) applied while being in proximity to the electronic device ED or being close to the electronic device ED by a predetermined distance. Additionally, the external input may have various types such as force, pressure, temperature, and light.

The display surface IS of the electronic device ED may be divided into a transmission region TA and a bezel region BZA. The transmission region TA may be a region where the image IM is displayed. The user views the image IM through the transmission region TA. In an embodiment, the transmission region TA is illustrated as a rectangular shape with rounded corners. However, this is merely an example, and the transmission region TA may have various shapes and is not limited to any one embodiment of the invention.

The bezel region BZA is adjacent to the transmission region TA. The bezel region BZA may have a predetermined color. The bezel region BZA may surround the transmission region TA. Accordingly, a shape of the transmission region TA may be substantially defined by the bezel region BZA. However, this is an example, and the bezel region BZA may be disposed adjacent to only one side of the transmission region TA or may be omitted. The electronic device ED according to an embodiment of the invention may include various embodiments and is not limited to any one embodiment.

In an embodiment, as shown in FIG. 1, the electronic device ED may include a display device DD and an outer case (or housing) EDC. In an embodiment, as shown in FIG. 2, the display device DD may include a window WM, a display module DM, a driving module EM, an optical film OTF, and a lower module LM. The display module DM may include a display panel DP and an input sensor ISP disposed on the display panel DP. The display panel DP generates the image IM, and the input sensor ISP acquires coordinate information about the external input (for example, a touch event). The lower module LM may include various functional layers having a plate shape extending along the first direction DR1 and the second direction DR2 as illustrated in FIG. 2. However, shapes of the functional layers included in the lower module LM may be different from each other.

The window WM may include or be made of a transparent material capable of emitting images. In an embodiment, for example, the window WM may include or be made of glass, sapphire, plastic, or the like. In an embodiment, the window WM may be defined by a single layer but is not limited thereto and may include multiple layers. In an embodiment, although not illustrated, the bezel region BZA of the display device DD described above may be provided as a region in which a material having a predetermined color is substantially printed in one region of the window WM.

The display module DM may include the display panel DP and the input sensor ISP. The display panel DP according to an embodiment of the invention may be a light-emitting display panel but is not particularly limited thereto. In an embodiment, for example, the display panel DP may be an organic light-emitting display panel, an inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include quantum dots, quantum rods, and the like. Hereinafter, embodiments where the display panel DP is the organic light-emitting display panel will be described as an example, but not being limited thereto.

The input sensor ISP may be “directly disposed” on the display panel DP. According to an embodiment of the invention, the input sensor ISP may be formed on the display panel DP by a continuous process. That is, when the input sensor ISP is disposed directly on the display panel DP, an adhesive film for bonding the input sensor ISP and the display panel DP is not disposed between the input sensor ISP and the display panel DP.

The optical film OTF reduces a reflectance for external light entering from above the window WM. The optical film OTF according to an embodiment of the invention may include a retarder and a polarizer. The retarder may be a film-type or a liquid-crystal-coating-type retarder and may include a λ/2 retarder and/or a λ/4 retarder. The polarizer may also be a film-type or a liquid-crystal-coating type polarizer. The film-type retarder or polarizer may include a stretchable synthetic resin film, and the liquid-crystal-coating-type retarder or polarizer may include liquid crystals arranged in a predetermined array. The retarder and polarizer may be implemented as a single polarizing film. The optical film OTF may further include a protective film disposed on an upper portion or a lower portion of the polarizing film.

The optical film OTF may be disposed on the input sensor ISP. That is, the optical film OTF may be disposed between the input sensor ISP and the window WM. The input sensor ISP, the optical film OTF, and the window WM may be bonded to each other through an adhesive layer.

Referring to FIG. 3, an optical adhesive layer AF1 is disposed between the input sensor ISP and the optical film OTF, and a window adhesive layer AF2 is disposed between the optical film OTF and the window WM. Accordingly, the optical film OTF is bonded to the input sensor ISP by the optical adhesive layer AF1, and the window WM is bonded to the optical film OTF by the window adhesive layer AF2.

In an embodiment of the invention, for example, each of the adhesive layers AF1 and AF2 may include an optically clear adhesive (OCA) film. However, a material of each of the adhesive layers AF1 and AF2 is not limited thereto and may include a typical adhesive or a bonding agent. In an embodiment, for example, each of the adhesive layers AF1 and AF2 may include a pressure sensitive adhesive (PSA), an optically clear adhesive (OCA), or an optical clear resin (OCR).

Between the display module DM and the window WM, functional layers for performing different functions, for example, a protective layer, may be additionally disposed in addition to the optical film OTF.

The display module DM may display the image in response to an electrical signal and may transmit/receive information about the external input. The display module DM may be defined as an active region AA and a peripheral region NAA. The active region AA may be defined as a region which emits the image provided from the display module DM.

The peripheral region NAA is adjacent to the active region AA. For example, the peripheral region NAA may surround the active region AA. However, this is merely an example, and the peripheral region NAA may be defined in various shapes and is not limited to any one embodiment of the invention. According to an embodiment, the active region AA of the display module DM may correspond to at least a portion of the transmission region TA.

According to an embodiment of the invention, as shown in FIG. 2, the display module DM may include a first region A1, a second region A2, and a third region A3 disposed (or sequentially arranged) along the second direction DR2. The first region A1 may include the active region AA and a portion of the peripheral region NAA, and the second region A2 and the third region A3 may include a remaining portion of the peripheral region NAA. The second region A2 may be a bending region which is bent with respect to a bending axis (AX in FIG. 4), and the first region A1 and the third region A3 may be non-bending regions.

The third region A3 may be disposed below the first region A1 in a state in which the second region A2 is bent with respect to the bending axis (AX in FIG. 4). Accordingly, the driving module EM disposed in the third region A3 may be disposed below the first region A1 in a state in which the second region A2 is bent.

A length of each of the second and third regions A2 and A3 in the first direction DR1 may be less than or equal to a length of the first region A1 in the first direction DR1. A region with a shorter length in the bending axis direction (i.e., the first direction DR1) may be bent more easily.

The driving module EM may control the drive of the display module DM. The driving module EM may include a flexible circuit film FCB and a driving chip DIC. The flexible circuit film FCB may be electrically connected to the display panel DP. The flexible circuit film FCB may be bonded to an end of the third region A3 of the display module DM through a bonding process. The flexible circuit film FCB may be electrically connected to the display module DM through an anisotropic conductive adhesive layer. The driving chip DIC may be disposed or mounted on the third region A3 of the display module DM. The driving chip DIC may include driving circuits for driving pixels of the display panel DP, for example, a data driving circuit. According to an embodiment, the flexible circuit film FCB may include a ground line (not shown) for discharging static electricity flowing into the flexible circuit film FCB or static electricity flowing into the input sensor ISP.

After the process of bending the second region A2, a process of compressing the flexible circuit film FCB in a state in which the second region A2 is bent may be performed. In this process, when components included in the lower module LM include a cushion layer containing a synthetic resin foam or the like, elements included in the flexible circuit film FCB may be transferred to the display panel DP during the compression process, thereby causing the surface quality of the display panel DP to be reduced.

The driving module EM may further include a plurality of driving elements mounted on the flexible circuit film FCB. The plurality of driving elements may include a circuit unit for converting a signal input from the outside into a signal for the driving chip DIC or into a signal for driving the display module DM.

The lower module LM is disposed on a back surface of the display module DM. The lower module LM is disposed on the back surface of the display module DM to improve an impact resistance of the display device DD. The lower module LM may be fixed to the back surface of the display module DM through the adhesive layer.

In a state where the second region A2 and the third region A3 of the display module DM are bent, the third region A3 of the display module DM and the flexible circuit film FCB may be disposed on a back surface of the lower module LM.

The outer case EDC may be coupled to the window WM to define the exterior of the electronic device ED. The outer case EDC accommodates the display device DD. The outer case EDC absorbs an impact applied from the outside and prevents foreign substances/moisture, and the like from penetrating into the electronic device ED, thereby protecting the components accommodated in the outer case EDC. In an embodiment, for example, the outer case EDC may be provided in a form in which a plurality of accommodation members are combined.

FIG. 4 is a cross-sectional view of a display device illustrating the display panel in a bent state according to an embodiment of the invention is bent. FIG. 4 is a cross-sectional view of the display device DD adjacent to the second region A2 in a state in which the second region A2 is bent with respect to the bending axis AX extending along the first direction DR1.

In an embodiment, the display device DD may include the window WM, the optical film OTF, the display module DM, and the lower module LM. The lower module LM may include a first protective member PF1, a second protective member PF2, and a cover member CM.

The window WM according to an embodiment may include a base part WB, a hard coating layer HC, and a bezel pattern BP. The base part WB may include an optically transparent insulating material. In an embodiment, for example, the base part WB may include a glass substrate or a synthetic resin film. The hard coating layer HC for protecting the base part WB may be disposed on either a front surface or a back surface of the base part WB. The hard coating layer HC may effectively prevent damage of the base part WB caused by scratches or the like. In addition, an anti-fingerprint layer may be further disposed on the base part WB.

The bezel pattern BP defines the bezel region BZA (see FIG. 1) of the window WM. The bezel pattern BP may be disposed adjacent to an edge of the back surface of the base part WB.

The bezel pattern BP is a colored layer and may be formed through coating. The bezel pattern BP may include a polymer resin and a pigment mixed in the polymer resin. The polymer resin may be, for example, an acrylic resin or a polyester, and the pigment may be a carbon-based pigment.

The optical film OTF may be disposed under the window WM. The optical film OTF may reduce the reflectance for the external light incident from the window WM. The window WM and the optical film OTF may be bonded to each other through the optical adhesive layer AF1. The display module DM and the optical film OTF may be bonded to each other through the window adhesive layer AF2.

The lower module LM may include the first protective member PF1, the cover member CM, and the second protective member PF2. The first protective member PF1 may be disposed at a lower portion of the first region A1. The first protective member PF1 may be bonded to a lower portion (or an inner surface portion) of the display panel DP overlapping the first region A1 through a first adhesive layer AM1.

The second protective member PF2 may be disposed in the third region A3. The second protective member PF2 may be in contact with a heat dissipation layer CS of the cover member CM through a second adhesive layer AM2.

The second protective member PF2 may be bonded to a lower portion (or an inner surface portion) of the display panel DP overlapping the third region A3 through a third adhesive layer AM3. Each of the first and second protective members PF1 and PF2 may be a protective film typically used in the art.

In an embodiment of the invention, for example, each of the first to third adhesive layers AF1, AF2 and AF3 may include an optically clear adhesive (OCA) film. However, the material of each of the first to third adhesive layers AF1, AF2 and AF3 is not limited thereto and may include a typical adhesive or bonding agent. In an embodiment, for example, each of the first to third adhesive layers AF1, AF2 and AF3 may include a pressure sensitive adhesive (PSA), an optically clear adhesive (OCA), or an optical clear resin (OCR).

The cover member CM may be disposed under the first protective member PF1. The cover member CM may have (or perform) multiple functions. In an embodiment, for example, the cover member CM may have a light-blocking function, a heat-radiating function, a cushioning function, and the like.

The cover member CM according to an embodiment may include an intermediate layer PT, a first adhesive PSA1, a second adhesive PSA2, and the heat dissipation layer CS.

The first adhesive PSA1 may be disposed on the intermediate layer PT. The first adhesive PSA1 may be in direct contact with the first protective member PF1. The second adhesive PSA2 may be disposed under the intermediate layer PT, and the heat dissipation layer CS may be disposed under the second adhesive PSA2. The second adhesive layer AM2 may be disposed between the heat dissipation layer CS and the second protective member PF2.

The intermediate layer PT may include a polymer material. In an embodiment, for example, the intermediate layer PT may include polyethylene terephthalate (PET). The intermediate layer PT may perform a light-blocking function, which will be described later.

In an embodiment, each of the first and second adhesives PSA1 and PSA2 may include a pressure sensitive adhesive (PSA). According to an embodiment of the invention, the first and second adhesives PSA1 and PSA2 may perform a cushioning function by controlling thicknesses and moduli of the first and second adhesives PSA1 and PSA2. Accordingly, in the electronic device ED (see FIG. 1) according to an embodiment of the invention, the cushion layer including a synthetic resin foam, or the like may be omitted.

The heat dissipation layer CS may effectively dissipate heat generated from the display module DM. The heat dissipation layer CS may include at least one selected from graphite, copper (Cu), or aluminum (Al) having high heat dissipation characteristics, but is not limited thereto. The heat dissipation layer CS may not only improve heat dissipation characteristics but may also have electromagnetic wave blocking or electromagnetic wave absorbing characteristics.

The display device DD according to an embodiment may include a protective layer RM. The protective layer RM may be disposed in (or fill) an inner space defined by a back surface of the display module DM, a side surface of the first protective member PF1, a side surface of the cover member CM, a side surface of the second protective member PF2, and a side surface of each of the adhesive layers AM1, AM2, and AM3 which overlap the second region A2 when the display module DM is bent.

As the protective layer RM is disposed in the inner space, the protective layer RM may support the display module DM such that the display module DM maintains the shape of the second region A2 during bending. In addition, the protective layer RM may effectively prevent foreign substances or the like from entering the interior of the display module DM through the second region A2. The protective layer RM according to an embodiment may include a resin.

The display panel DP according to an embodiment may further include a bending cover layer BCV disposed on the second region A2. The bending cover layer BCV may reduce a stress applied to the second region A2 when the second region A2 is bent and may protect the second region A2. The bending cover layer BCV may include an organic material or may be provided in a tape form and is not limited to any one embodiment of the invention.

The display device DD according to an embodiment may further include a conductive film CV disposed in the third region A3. The conductive film CV may cover the driving chip DIC to effectively prevent static electricity introduced from the outside from damaging the driving chip DIC and to effectively prevent foreign substances, and the like from penetrating into the driving chip DIC. In addition, the conductive film CV may effectively prevent an impact from being applied to the driving chip DIC.

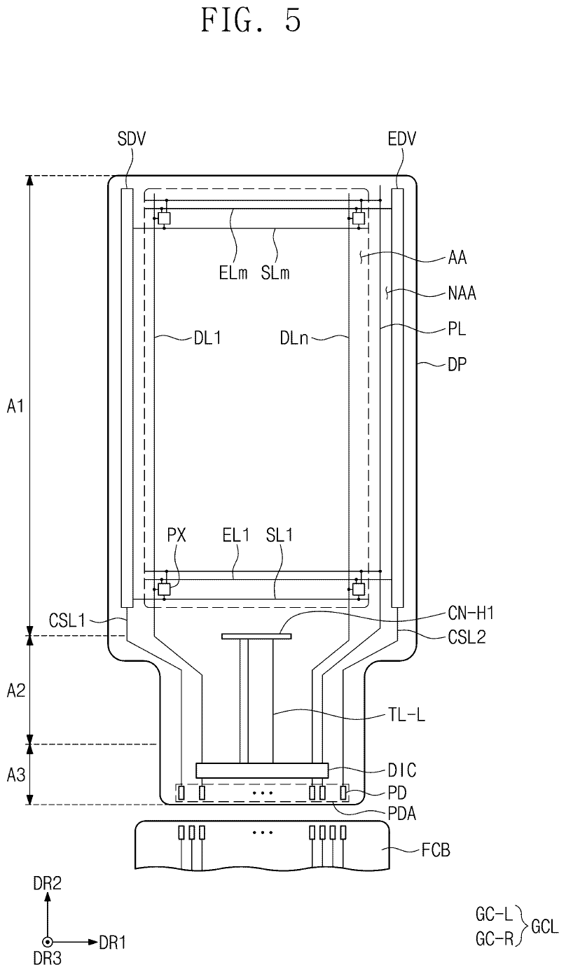

FIG. 5 is a plan view of a display panel according to an embodiment of the invention.

The display panel DP according to an embodiment of the invention may be divided into the first region A1, the second region A2, and the third region A3 arranged along the second direction DR2. The first to third regions A1, A2, and A3 of the display panel DP illustrated in FIG. 5 correspond to the first to third regions A1, A2, and A3 of the display module DM described above with reference to FIG. 2, respectively. In the disclosure, the wording “regions/portions correspond to regions/portions” means that they overlap each other and is not limited to the meaning that they have a same area as each other.

The display panel DP according to an embodiment may include the active region AA in which pixels PX are arranged and the peripheral region NAA adjacent to the active region AA. The active region AA and the peripheral region NAA correspond to the active region AA and the peripheral region NAA described above with reference to FIG. 2, respectively. The active region AA corresponds to a region of the first region A1 in which the pixels PX are arranged, and the peripheral region NAA is defined as a remaining region excluding the region in which the pixels PX are arranged.

The first region A1 may include the active region AA and a portion of the peripheral region NAA, and the second region A2 and the third region A3 may include a remaining portion of the peripheral region NAA.

The display panel DP may include a scan driver SDV, an emission driver EDV, pads PD, and the driving chip DIC in the peripheral region NAA. In the present embodiment, the driving chip DIC may be a data driver.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, a power line PL, and a plurality of pads PD. Here, “m” and “n” are natural numbers. The pixels PX may be connected to the scan lines SL1 to SLm, the data lines DL1 to DLn and the emission lines EL1 to ELm.

The scan lines SL1 to SLm may extend in the first direction DR1 and be connected to the scan driver SDV. The data lines DL1 to DLn may extend in the second direction DR2 and be connected to the driving chip DIC disposed in the third region A3 from the first region A1 via the second region A2. The emission lines EL1 to ELm may extend in the first direction DR1 and be connected to the emission driver EDV.

A power line PL may include a portion extending in the first direction DR1 and a portion (not illustrated) extending in the second direction DR2. The portion extending in the first direction DR1 and the portion extending in the second direction DR2 may be disposed on different layers. The portion of the power line PL extending in the second direction DR2 may extend from the first region A1 to the third region A3 via the second region A2. The power line PL may provide a reference voltage to the pixels PX.

The first control line CSL1 is connected to the scan driver SDV and may extend from the first region A1 to the third region A3 via the second region A2. The second control line CSL2 is connected to the emission driver EDV and may extend from the first region A1 to the third region A3 via the second region A2.

The pads PD may be disposed adjacent to the end of the third region A3. The driving chip DIC, the power line PL, the first control line CSL1, and the second control line CSL2 may be connected to the pads PD. The flexible circuit film FCB may be disposed on the display panel DP while overlapping the end of the third region A3 of the display panel DP. The flexible circuit film FCB may include pads corresponding to the pads PD and may be electrically connected to the pads PD through an anisotropic conductive film (ACF).

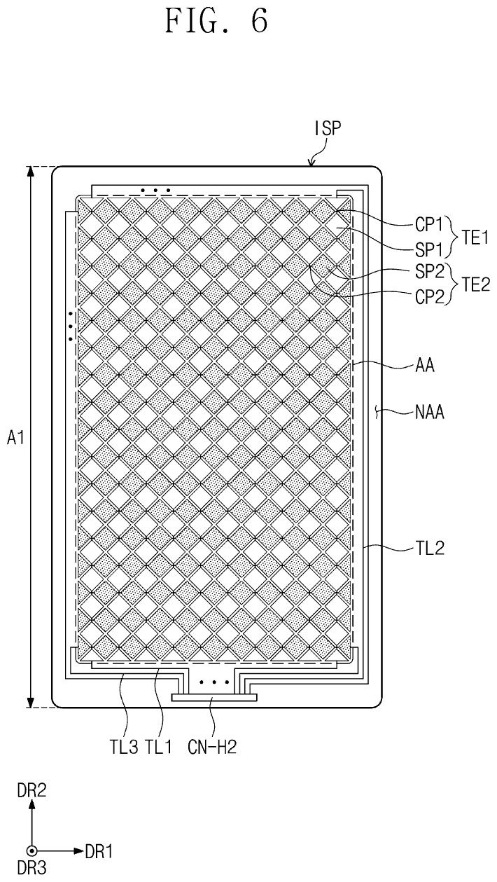

The display panel DP according to an embodiment may be provided with a first contact hole CN-H1 defined in the peripheral region NAA. The display panel DP may include extended sensing lines TL-L. The extended sensing lines TL-L may extend to the third region A3 via the first region A1 and the second region A2. The extended sensing lines TL-L may be connected in one-to-one correspondence to corresponding sensing lines among sensing lines TL1, TL2, and TL3 (see FIG. 6) to be described later via the first contact hole CN-H1. In an embodiment, for example, one-end portions of the extended sensing lines TL-L may be exposed from the first contact hole CN-H1 to be connected to the sensing lines TL1, TL2, and TL3 (see FIG. 6), and the other-end portions of the extended sensing lines TL-L may be connected to the pads PD.

Although FIG. 5 illustrates an embodiment where the extended sensing lines TL-L are disposed between the data lines DL1 to DLn, an embodiment of the invention is not limited thereto, and the data lines DL1 to DLn may be disposed between the extended sensing lines TL-L. Accordingly, the first contact hole CN-H1 may be provided in plurality with the data lines DL1 to DLn therebetween and are not limited to an embodiment of the invention.

Referring to FIG. 6, the input sensor ISP according to an embodiment may include sensing electrodes TE1 and TE2 and sensing lines TL1, TL2, and TL3. In an embodiment where the input sensor ISP is directly formed on the display panel DP through a continuous process, the sensing electrodes TE1 and TE2 may be formed only in the active region AA overlapping the first region A1 of the display panel DP.

The input sensor ISP may acquire information about an external input through a change in electrostatic capacitance between the first sensing electrodes TE1 and the second sensing electrodes TE2. The first sensing electrodes TE1 are arranged along the first direction DR1, and each of the first sensing electrodes TE1 extends along the second direction DR2. The first sensing electrodes TE1 may include first sensing patterns SP1 and first connection patterns CP1, respectively.

The first sensing patterns SP1 are disposed in the active region AA. The first sensing patterns SP1 included in one of the first sensing electrodes TE1 may be arranged along the second direction DR2. The first sensing patterns SP1 may have a rhombus shape. However, this is illustrated as an example, and the first sensing patterns SP1 may have various shapes and are not limited to any one embodiment of the invention.

The first connection pattern CP1 is disposed in the active region AA. The first connection pattern CP1 may be disposed between adjacent first sensing patterns SP1. The first connection pattern CP1 and the first sensing pattern SP1 may be disposed on different layers and may be connected to each other through a contact hole.

The second sensing electrodes TE2 are arranged along the second direction DR2, and each of the second sensing electrodes TE2 extends along the first direction DR1. The second sensing electrodes TE2 may include second sensing patterns SP2 and second connection patterns CP2, respectively.

The second sensing patterns SP2 may be spaced apart from the first sensing patterns SP1. The first sensing patterns SP1 and the second sensing patterns SP2 may not be in contact with each other to transmit/receive independent electrical signals.

The second sensing patterns SP2 are disposed in the active region AA. The second sensing patterns SP2 included in one of the second sensing electrodes TE2 may be arranged along the second direction DR1. The second sensing patterns SP2 and the first sensing patterns SP1 may have the same shape. In an embodiment, for example, the second sensing patterns SP2 may have a rhombus shape in a plan view or when viewed in the third direction DR3. However, this is illustrated as an example, and the second sensing patterns SP2 may have various shapes and are not limited to any one embodiment of the invention.

The second connection pattern CP2 may be disposed between adjacent second sensing patterns SP2. The second sensing patterns SP2 and the second connection patterns CP2, which are substantially included in one of the second sensing electrodes TE2, may be formed in an integral shape or an integral pattern.

According to an embodiment, the first sensing patterns SP1, the second sensing patterns SP2, and the second connection patterns CP2 may be disposed at the same layer and the first sensing patterns SP1 may be disposed on a different layer. The first sensing patterns SP1, the second sensing patterns SP2, and the second connection patterns CP2 may be provided as a plurality of mesh lines extending in a diagonal direction of each of the first and second directions DR1 and DR2.

The sensing lines TL1, TL2, and TL3 are disposed in the peripheral region NAA. The sensing lines TL1, TL2, and TL3 may include the first sensing lines TL1, the second sensing lines TL2, and the third sensing lines TL3.

One-end portions of the first sensing lines TL1 are respectively connected to the first sensing electrodes TE1. In an embodiment, the first sensing lines TL1 are connected to lower end portions of opposite end portions of the first sensing electrodes TE1, respectively. One-end portions of the second sensing lines TL2 are respectively connected to upper end portions of the opposite sides of the first sensing electrodes TE1. According to an embodiment of the invention, the first sensing electrodes TE1 may be connected to the first sensing lines TL1 and the second sensing lines TL2, respectively. Therefore, in such an embodiment, the first sensing electrodes TE1, which have a relatively greater length than the second sensing electrodes TE2, may uniformly maintain the sensitivity for each region.

In the input sensor ISP according to an embodiment of the invention, either of the first sensing lines TL1 or the second sensing lines TL2 may be omitted, and the invention is not limited to any one embodiment.

One-end portions of the third sensing lines TL3 are respectively connected to one-end portions of the second sensing electrodes. In an embodiment, the third sensing lines TL3 are connected to left end portions of opposite end portions of the second sensing electrodes TE2, respectively.

A second contact hole CN-H2 formed through at least one of the insulating layers included in the input sensor ISP may be defined in the input sensor ISP. The second contact hole CN-H2 may overlap the first contact hole CN-H1 defined in the peripheral region NAA of the display panel DP.

The other-end portions of the sensing lines TL1, TL2, and TL3 may each be disposed in the second contact hole CN-H2. The other-end portions of the sensing lines TL1, TL2, and TL3 disposed in the second contact hole CN-H2 may be connected to the extended sensing lines TL-L (see FIG. 5). The sensing lines TL1, TL2, and TL3 may be connected to the pads PD (see FIG. 5) through the extended sensing lines TL-L disposed on the display panel DP (see FIG. 5).

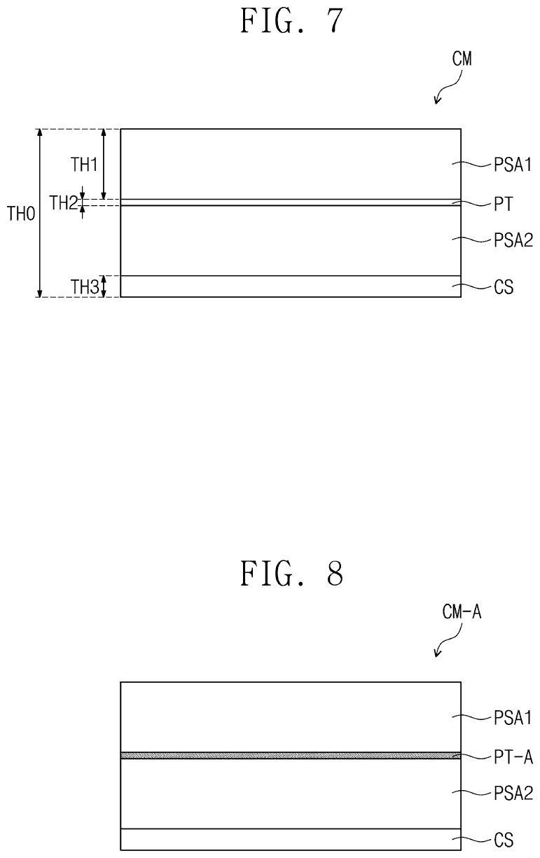

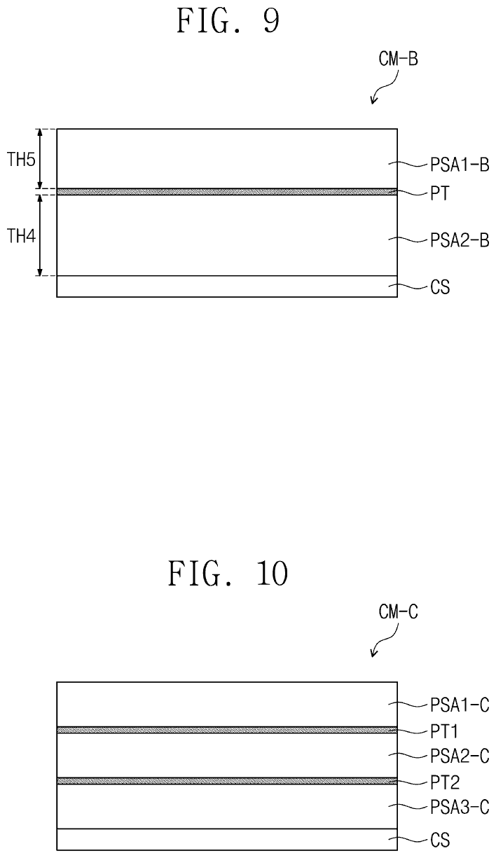

FIG. 7 is a cross-sectional view of a cover member according to an embodiment of the invention. FIG. 8 is a cross-sectional view of a cover member according to an embodiment of the invention. FIG. 9 is a cross-sectional view of a cover member according to an embodiment of the invention. FIG. 10 is a cross-sectional view of a cover member according to an embodiment of the invention.

Embodiments of the cover members to be described with reference to FIGS. 7 to 10 may be applied to the cover member CM described above with reference to FIG. 4, and the same/similar reference numerals are given to the same/similar components as the components described above with reference to FIG. 4, and any repetitive detailed descriptions thereof will be omitted.

Referring to FIG. 7, the cover member CM according to an embodiment may have a plurality of functions. In an embodiment, for example, the cover member CM may have a heat dissipation function, a cushion function, or the like.

The cover member CM may include an intermediate layer PT, a first adhesive PSA1, a second adhesive PSA2, and a heat dissipation layer CS.

The intermediate layer PT may function as a support on which the first adhesive PSA1 and the second adhesive PSA2 may be disposed. The first adhesive PSA1 may be disposed on the intermediate layer PT. The first adhesive PSA1 may be in direct contact with the first protective member PF1 (see FIG. 4). The second adhesive PSA2 may be disposed under the intermediate layer PT, and the heat dissipation layer CS may be disposed under the second adhesive PSA2. The second adhesive PSA2 may be in direct contact with the heat dissipation layer CS. The second protective member PF2 (see FIG. 4) may be disposed under the heat dissipation layer CS, and the second adhesive layer AM2 may be in direct contact with the second protective member PF2 (see FIG. 4).

In an embodiment, a thickness (i.e., a total thickness) of the cover member CM may be in a range of about 100 micrometers (μm) to about 250 μm. A first thickness TH1 of each of the first and second adhesives PSA1 and PSA2 may be in a range of about 5 μm to about 200 μm. In an embodiment, the first thicknesses TH1 of the first and second adhesives PSA1 and PSA2 may be the same as each other. A second thickness TH2 of the intermediate layer PT may be in a range of about 4 μm to about 100 μm. According to an embodiment of the invention, the second thickness TH2 of the intermediate layer PT may be smaller than the first thickness TH1 of each of the first and second adhesives PSA1 and PSA2. A third thickness TH3 of the heat dissipation layer CS may be in a range of about 5 μm to about 100 μm.

In an embodiment, each of the first and second adhesives PSA1 and PSA2 may include a pressure sensitive adhesive (PSA). A modulus (e.g., Young's modulus) of each of the first and second adhesives PSA1 and PSA2 may be in a range of about 0.003 Mpa to in a range of about 0.5 Mpa.

According to an embodiment, the moduli of the first and second adhesives PSA1 and PSA2 may be different from each other. In an embodiment, for example, the modulus of the first adhesive PSA1 disposed on the upper side may be smaller than the modulus of the second adhesive PSA2 disposed on the lower side.

According to an embodiment of the invention, the first and second adhesives PSA1 and PSA2 may have a cushion function by adjusting the thickness and modulus thereof. In the display device ED (see FIG. 2) according to an embodiment of the invention, since layers containing a pressure sensitive adhesive (PSA) is provided as a laying having a cushioning function in place of a foam, it is possible to effectively prevent a defect in which components of the flexible circuit film FCB (see FIG. 4) are transferred to the display panel DP (see FIG. 4) in a process of compressing the flexible circuit film FCB.

In such an embodiment, since the components included in the cover member CM are simplified, the manufacturing cost of the cover member CM may be reduced.

The intermediate layer PT may include a polymer material. In an embodiment, for example, the intermediate layer PT may include polyethylene terephthalate (PET).

The heat dissipation layer CS may include at least one selected from graphite, copper (Cu), or aluminum (Al) having high heat dissipation characteristics, but is not limited thereto. The heat dissipation layer CS may not only improve heat dissipation characteristics, but also have electromagnetic wave blocking or electromagnetic wave absorbing characteristics.

Referring to FIG. 8, a cover member CM-A according to an embodiment may include a plurality of functions. In an embodiment, for example, the cover member CM-A may have a light blocking function, a heat dissipation function, a cushion function, and the like.

The cover member CM-A may include an intermediate layer PT-A, a first adhesive PSA1, a second adhesive PSA2, and a heat dissipation layer CS. An arrangement relationship between the intermediate layer PT-A, the first adhesive PSA1, the second adhesive PSA2, and the heat dissipation layer CS included in the cover member CM-A may correspond to an arrangement relationship between the components included in the cover member CM described with reference to FIG. 7.

The intermediate layer PT-A according to an embodiment may have a light blocking function. The intermediate layer PT-A may include polyethylene terephthalate (PET). The intermediate layer PT-A according to an embodiment may have a black color. The intermediate layer PT-A may include a pigment mixed with polyethylene terephthalate (PET). The polymer resin may be, for example, a carbon-based pigment.

According to an embodiment, since the intermediate layer PT-A includes a black color, components disposed under the intermediate layer PT-A may be prevented from being viewed on the display panel DP (see FIG. 4).

Referring to FIG. 9, a cover member CM-B according to an embodiment may have a plurality of functions. In an embodiment, for example, the cover member CM-B may include a heat dissipation function, a cushion function, and the like.

The cover member CM-B may include an intermediate layer PT, a first adhesive PSA1-B, a second adhesive PSA2-B, and a heat dissipation layer CS. An arrangement relationship between the intermediate layer PT, the first adhesive PSA1-B, the second adhesive PSA2-B, and the heat dissipation layer CS included in the cover member CM-B may correspond to the arrangement relationship between the components included in the cover member CM described with reference to FIG. 7.

According to an embodiment, the first adhesive PSA1-B and the second adhesive PSA2-B may have different thicknesses from each other. In an embodiment, for example, the first adhesive PSA1-B may have a fourth thickness TH4, and the second adhesive PSA2-B may have a fifth thickness TH5. The fifth thickness TH5 of the second adhesive PSA2-B may be smaller than the fourth thickness TH4 of the first adhesive PSA1-B. In such an embodiment, the modulus of the first adhesive PSA1-B may be smaller than the modulus of the second adhesive PSA2-B.

Referring to FIG. 10, a cover member CM-C according to an embodiment may include an intermediate layer PT1, an additional intermediate layer PT2, a first adhesive PSA1-C, a second adhesive PSA2-C, an additional adhesive PSA3-C, and a heat dissipation layer CS.

The intermediate layer PT1 and the additional intermediate layer PT2 may function as a support on which the first adhesive PSA1-C, the second adhesive PSA2-C, and the additional adhesive PSA3-C may be disposed. Each of the intermediate layer PT1 and the additional intermediate layer PT2 may include polyethylene terephthalate (PET). At least one selected from the intermediate layer PT1 or the additional intermediate layer PT2 may have a black color. Each of the first adhesive PSA1-C, the second adhesive PSA2-C, and the additional adhesive PSA3-C may include a pressure sensitive adhesive (PSA).

The first adhesive PSA1-C may be disposed on the intermediate layer PT1. The first adhesive PSA1-C may be in direct contact with the first protective member PF1 (see FIG. 4). The second adhesive PSA2-C may be disposed under the intermediate layer PT1. The additional intermediate layer PT2 may be disposed under the second adhesive PSA2-C. The additional adhesive PSA3-C may be disposed under the additional intermediate layer PT2. The heat dissipation layer CS may be disposed under the additional adhesive PSA3-C. The second protective member PF2 (see FIG. 4) may be disposed under the heat dissipation layer CS, and the second adhesive layer AM2 (see FIG. 4) may be disposed between the second protective member PF2 (see FIG. 4) and the heat dissipation layer CS.

In an embodiment, the first adhesive PSA1-C, the second adhesive PSA2-C, and the additional adhesive PSA3-C may have a same thickness as each other. However, the invention is not limited thereto, and a thickness of the second adhesive PSA2-C may be greater than a thickness of the first adhesive PSA1-C, may be smaller than a thickness of the additional adhesive PSA3-C. However, the invention is not limited to any one embodiment.

According to an embodiment of the invention, since a cushion layer disposed under a display panel includes adhesives or defined by adhesive layers, it is possible to effectively prevent components of a flexible circuit film from being transferred to the display panel in a process of compressing the flexible circuit film. Accordingly, a display device with improved surface quality may be provided. In such an embodiment, since components of a lower module disposed under the display module are simplified, the manufacturing cost of the lower module may be reduced.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel including a first region including an active region in which pixels are arranged, a second region bent with respect to a bending axis extending along a first direction, and a third region spaced apart from the first region along a second direction crossing the first direction with the second region therebetween; and
a lower module disposed between the first region and the third region in a state where the second region is bent, wherein the lower module includes a first protective member disposed on the first region, a second protective member disposed on the third region, and a cover member disposed between the first protective member and the second protective member,
wherein the cover member includes
an intermediate layer,
a first adhesive disposed on the intermediate layer and in contact with the first protective member,
a second adhesive disposed under the intermediate layer, and
a heat dissipation layer between the second protective member and the second adhesive.

2. The display device of claim 1, wherein each of the first adhesive and the second adhesive comprises a pressure sensitive adhesive.

3. The display device of claim 1, wherein the intermediate layer comprises polyethylene terephthalate.

4. The display device of claim 3, wherein the intermediate layer has a black color.

5. The display device of claim 1, wherein a thickness of the cover member is in a range of about 100 μm to about 250 μm.

6. The display device of claim 1, wherein a thickness of the first adhesive and a thickness of the second adhesive are each in a range of about 5 μm to about 200 μm.

7. The display device of claim 1, wherein a thickness of the intermediate layer is in a range of about 4 μm to about 100 μm, and a thickness of the heat dissipation layer is in a range of about 5 μm to about 100 μm.

8. The display device of claim 1, wherein a modulus of the first adhesive and a modulus of the second adhesive are different from each other.

9. The display device of claim 1, wherein a modulus of the first adhesive and a modulus of the second adhesive are each in a range of about 0.003 Mpa to about 0.5 Mpa.

10. The display device of claim 1, wherein a thickness of the first adhesive is smaller than a thickness of the second adhesive.

11. The display device of claim 10, wherein a modulus of the first adhesive is smaller than a modulus of the second adhesive.

12. The display device of claim 1, wherein the cover member further comprises:
an additional intermediate layer disposed under the second adhesive; and
an additional adhesive disposed between the additional intermediate layer and the heat dissipation layer.

13. The display device of claim 1, further comprising:
an adhesive layer which bonds the second protective member and the heat dissipation layer to each other.

14. The display device of claim 1, further comprising:
a window disposed on the display panel; and
an optical film disposed between the display panel and the window.

15. The display device of claim 14, further comprising:
a transparent adhesive layer disposed between the window and the optical film,
wherein the transparent adhesive layer includes an optically clear adhesive film.

16. The display device of claim 1, further comprising:
a bending cover layer disposed on the second region and
a protective layer disposed in a space between the second region and a side surface of the first protective member facing the second region, a side surface of the cover member, and a side surface of the second protective member,
wherein the protective layer includes a resin.

17. An electronic device comprising:
window:
a display panel including a first region disposed in which pixels are arranged, a second region bent with respect to a bending axis extending along a first direction, and a third region spaced apart from the first region along a second direction crossing the first direction with the second region therebetween; and
a lower module disposed between the first region and the third region in a state where the second region is bent, wherein the lower module includes a first protective member disposed on the first region, a second protective member disposed on the third region, and a cover member disposed between the first protective member and the second protective member, and
a case coupled with the window,
wherein the cover member includes
an intermediate layer,
a first adhesive disposed on the intermediate layer and in contact with the first protective member,
a second adhesive disposed under the intermediate layer, and
a heat dissipation layer between the second protective member and the second adhesive.

18. The electronic device of claim 17, wherein each of the first adhesive and the second adhesive comprises a pressure sensitive adhesive.

19. The electronic device of claim 17, wherein the intermediate layer comprises polyethylene terephthalate.

20. The electronic device of claim 19, wherein the intermediate layer has a black color.
